(19) United States
(12) Patent Application Publication
(10) Pub. No.: US 2026/0055307 A1
(43) Pub. Date: Feb. 26, 2026

(54) LOW CORROSION HIGH REMOVAL RATE COMPOSITION FOR TUNGSTEN AND MOLYBDENUM CMP

(71) Applicant: ENTEGRIS, INC., Billerica, MA (US)

(72) Inventors: Kevin P. Dockery, Aurora, IL (US); Bosky Soni, North Aurora, IL (US); Tala Zubi, Tinley Park, IL (US); Jason Seabold, Oswego, IL (US); Rajshree Kothari, Aurora, IL (US); Na Zhang, Naperville, IL (US)

(21) Appl. No.: 19/290,604

(22) Filed: Aug. 5, 2025

Related U.S. Application Data
(60) Provisional application No. 63/684,968, filed on Aug. 20, 2024.

(51) Int. Cl. C09K 3/14; H01L 21/321

(52) U.S. Cl. CPC C09K 3/1463; H01L 21/3212

(57) ABSTRACT

A chemical mechanical polishing composition comprises, consists of, or consists essentially of a liquid carrier, colloidal silica particles dispersed in the liquid carrier; an iron-containing polishing accelerator; a stabilizer bound to the iron-containing polishing accelerator; an alkyl-N-oxide compound including an alkyl group having at least 8 carbon atoms; and a pH of less than about 4.

### BACKGROUND OF THE INVENTION

Chemical mechanical polishing (CMP) compositions and methods for polishing (or planarizing) the surface of a substrate are well known. Polishing compositions (also known as polishing slurries, CMP slurries, and CMP compositions) for polishing metal layers (such as tungsten) on a semiconductor substrate may include abrasive particles (e.g., including silica particles) dispersed in an aqueous carrier and various chemical additives such as an oxidizer (e.g., hydrogen peroxide), a rate accelerator (e.g., a catalyst), a corrosion inhibitor, and a pH buffer.

As transistor sizes continue to shrink, the use of conventional metal interconnect technology has become increasingly challenging. Recently, molybdenum has emerged as a candidate metal for advanced node applications, for example, to replace or supplement copper and/or tungsten in the lower metal layers of the interconnect structure (e.g., in the M1, M2, and/or M3 layers). Moreover, molybdenum may also be used as a liner for tungsten plugs and interconnects.

As noted above, CMP compositions commonly employ an oxidizer such as hydrogen peroxide. Tungsten and molybdenum both tend to be susceptible to hydrogen peroxide induced corrosion. Advanced node devices are generally highly susceptible to corrosion issues owing to the extremely small feature size of the metal structures. Moreover, achieving high tungsten and/or molybdenum polishing rates while providing necessary corrosion inhibition is difficult since known corrosion inhibitors tend to reduce polishing rates (often significantly). There is a need for CMP compositions that can polish both tungsten and molybdenum layers at suitably high removal rates while providing improved inhibition of tungsten and/or molybdenum corrosion.

### BRIEF SUMMARY OF THE INVENTION

A chemical mechanical polishing composition is disclosed. The composition comprises, consists of, or consists essentially of a liquid carrier, colloidal silica particles dispersed in the liquid carrier; an iron-containing polishing accelerator; a stabilizer bound to the iron-containing polishing accelerator; an alkyl-N-oxide compound including a first alkyl group having at least 8 carbon atoms; and a pH of less than about 4.

### DETAILED DESCRIPTION OF THE INVENTION

Chemical mechanical polishing compositions and methods for using those compositions to polish a substrate are disclosed. In one example embodiment, a chemical mechanical polishing composition comprises, consists essentially of, or consists of a liquid carrier, colloidal silica particles dispersed in the liquid carrier; an iron-containing polishing accelerator; a stabilizer bound to the iron-containing polishing accelerator; an alkyl-N-oxide compound including a first alkyl group having at least 8 carbon atoms; and a pH of less than about 4. A method for polishing a tungsten or molybdenum containing substrate includes contacting the substrate with one of the disclosed polishing compositions, moving the polishing composition relative to the substrate, and abrading the substrate to remove tungsten and/or molybdenum from the substrate and thereby polish the substrate.

The disclosed polishing compositions and corresponding (CMP methods) may confer significant advantages. In example embodiments, disclosed polishing compositions may advantageously polish both tungsten and molybdenum at high rates while suppressing both tungsten and molybdenum corrosion. The disclosed compositions may further provide improved topography (e.g., improved dishing and erosion in tungsten or molybdenum line features)

The polishing composition contains colloidal silica particles suspended (or dispersed) in a liquid carrier. The liquid carrier is used to facilitate the application of the colloidal silica particles and chemical additives to the surface of the substrate to be polished (e.g., planarized). The liquid carrier may be any suitable carrier (e.g., a solvent) including lower alcohols (e.g., methanol, ethanol, etc.), ethers (e.g., dioxane, tetrahydrofuran, etc.), water, and mixtures thereof. Preferably, the liquid carrier comprises, consists essentially of, or consists of water, more preferably deionized water.

The colloidal silica particles may include substantially any suitable colloidal silica particles. As used herein the term colloidal silica particles refers to silica particles that are prepared via a wet process rather than a pyrogenic or flame hydrolysis process which produces structurally different particles. The disclosed embodiments may include aggregated or non-aggregated colloidal particles (e.g., colloidal silica particles). Non-aggregated particles are individually discrete particles that may be spherical or nearly spherical in shape, but can have other shapes as well (such as generally elliptical, square, or rectangular cross-sections). Aggregated particles are particles in which multiple discrete primary particles are clustered or bonded together to form aggregates having generally irregular shapes.

The colloidal silica particles may have substantially any suitable particle size. The particle size of a particle suspended in a liquid carrier may be defined in the industry using various means. For example, the particle size may be defined as the diameter of the smallest sphere that encompasses the particle and may be measured using a number of commercially available instruments, for example, including the CPS Disc Centrifuge, Model DC24000HR (available from CPS Instruments, Prairieville, Louisiana) or the Zetasizer® available from Malvern Instruments®. The colloidal silica particles may have an average particle size of about 5 nm or more (e.g., about 10 nm or more, about 20 nm or more, about 30 nm or more, about 40 nm or more, or about 50 nm or more). The colloidal silica particles may have an average particle size of about 300 nm or less (e.g., about 250 nm or less, about 200 nm or less, about 180 nm or less, or about 150 nm or less). Accordingly, the colloidal silica particles may have an average particle size in a range bounded by any two of the above endpoints. For example, the colloidal silica particles may have an average particle size in a range from about 5 nm to about 300 nm (e.g., from about 10 nm to about 200 nm, from about 20 nm to about 200 nm, or from about 50 nm to about 150 nm).

The polishing composition may include substantially any suitable amount of the colloidal silica particles. If the polishing composition comprises too little colloidal silica, the composition may not exhibit a sufficient removal rate. In contrast, if the polishing composition comprises too much colloidal silica, then the polishing composition may exhibit undesirable polishing performance and/or may not be cost effective. Polishing composition configured for bulk removal operations (e.g., bulk tungsten and/or bulk molybdenum) generally relatively small amounts of the colloidal silica particles, for example, about 0.01 wt. % or more at point of use (e.g., about 0.02 wt. % or more, about 0.05 wt. % or more, about 0.1 wt. % or more, or about 0.15 wt. % or more). The concentration of colloidal silica particles in the polishing composition is generally less than about 10 wt. % at point of use (e.g., about 5 wt. % or less, about 3 wt. % or less, about 2 wt. % or less, or about 1.5 wt. % or less, or about 1 wt. % or less). Accordingly, the concentration of colloidal silica particles in the polishing composition may be bounded by any two of the aforementioned endpoints. For example, the polishing composition may include from about 0.01 wt. % to about 10 wt. % of the colloidal silica particles at point of use (e.g., from about 0.02 wt. % to about 2 wt. %, from about 0.05 wt. % to about 1 wt. %, or from about 0.1 wt. % to about 1 wt. %).

In certain advantageous embodiments, the colloidal silica particles may include cationic (positively charged) colloidal silica particles. Preferred cationic colloidal silica particles include cationic colloidal silica particles. The cationic colloidal silica particles may have a permanent positive charge or a non-permanent positive charge. For example, the cationic colloidal silica particles may have a permanent positive charge. By permanent positive charge it is meant that the positive charge on the silica particles is not readily reversible, for example, via flushing, dilution, filtration, and the like. A permanent positive charge may be the result, for example, of covalently bonding a cationic compound such as an aminosilane with the colloidal silica. A permanent positive charge is in contrast to a reversible positive charge that may be the result, for example, of an interaction between a cationic compound and the colloidal silica.

Cationic colloidal silica particles having a permanent positive charge may be prepared via treating (e.g., covalently bonding) the colloidal silica particles with an aminosilane compound as disclosed in commonly assigned U.S. Pat. Nos. 7,994,057 and 9,028,572 or in U.S. Pat. No. 9,382,450. Example cationic colloidal silica particles may be treated using any suitable treating method to obtain the permanently charged particles. For example, a quaternary aminosilane compound and the colloidal silica may be added simultaneously to some or all of the other components in the polishing composition. Alternatively, the colloidal silica particles may be treated with a quaternary aminosilane compound (e.g., via a heating a mixture of the colloidal silica and the aminosilane) prior to mixing with the other components of the polishing composition. Colloidal silica particles having a permanent positive charge may also be obtained by incorporating a chemical species, such as an aminosilane compound, in the colloidal silica particles as disclosed in in commonly assigned U.S. Pat. No. 9,422,456.

Cationic colloidal silica particles having a non-permanent positive charge may be prepared via introducing a cationic surfactant into the polishing composition, for example, as disclosed commonly assigned U.S. Pat. No. 9,631,122. Such cationic surfactants may include, for example, one or a combination of tetrabutylammonium, tetrapentylammonium, tetrabutylphosphonium, tributylmethylphosphonium, tributyloctylphosphonium, and benzyltributylammonium.

In advantageous embodiments, cationic colloidal silica particles have a zeta potential of about 10 mV or more (e.g., about 15 mV or more, about 20 mV or more, about 25 mV or more, or about 30 mV or more) in the polishing composition (e.g., in a pH range from about 1 to about 4 and in the presence of the various chemical additives disclosed below). The cationic colloidal silica particles may also have a zeta potential of about 60 mV or less (e.g., about 55 mV or less or about 50 mV or less) in the polishing composition. For example, the cationic colloidal silica particles may have a zeta potential in a range from about 10 mV to about 60 mV (e.g., about 20 mV to about 60 mV, or about 25 mV to about 50 mV) in the polishing composition.

It will be appreciated that the zeta potential of a particle refers to the electrical potential difference between the electrical charge of the ions surrounding the particle and the electrical charge of the bulk solution of the polishing composition (e.g., the liquid carrier and any other components dissolved therein) and that the zeta potential generally depends on the pH and ionic strength (e.g., as indicated via a conductivity measurement) of the aqueous medium. The zeta potential of a dispersion such as a polishing composition may be measured using commercially available instrumentation such as the Zetasizer available from Malvern Instruments, the ZetaPlus Zeta Potential Analyzer available from Brookhaven Instruments, and/or an electro-acoustic spectrometer available from Dispersion Technologies, Inc.

The polishing composition is generally acidic having a pH of less than about 5. The polishing composition may have a pH of about 1 or more (e.g., about 1.5 or more or about 2 or more). Moreover, the polishing composition may have a pH of about 5 or less (e.g., about 4.5 or less, about 4 or less, about 3.5 or less, or about 3 or less). Accordingly, the polishing composition may have a pH in a range bounded by any two of the aforementioned endpoints, for example, in a range from about 1 to about 5 (e.g., from about 1 to about 4, from about 1.5 to about 4, from about 2 to about 4, from about 2 to about 3.5, or from about 2 to about 3).

The pH of the polishing composition may be achieved and/or maintained by any suitable means. The polishing composition may include substantially any suitable pH adjusting agents or buffering systems. For example, suitable pH adjusting agents may include nitric acid, sulfuric acid, phosphoric acid, phthalic acid, citric acid, adipic acid, oxalic acid, malonic acid, maleic acid, ammonium hydroxide, and the like while suitable buffering agents may include phosphates, sulfates, acetates, malonates, oxalates, borates, ammonium salts, and the like.

The disclosed polishing composition may include an iron-containing polishing rate accelerator (e.g., a tungsten or molybdenum polishing rate accelerator). An iron-containing accelerator as used herein is an iron-containing chemical compound that may increase the removal rate of tungsten or molybdenum during a metal CMP operation. For example, the iron-containing accelerator may include a soluble iron-containing catalyst such as is disclosed in U.S. Pat. Nos. 5,958,288 and 5,980,775. Such an iron-containing catalyst may be soluble in the liquid carrier and may include, for example, ferric (iron III) or ferrous (iron II) compounds such as iron nitrate, iron sulfate, iron halides, including fluorides, chlorides, bromides, and iodides, as well as perchlorates, perbromates and periodates, and organic iron compounds such as iron acetates, carboxylic acids, acetylacetonates, citrates, gluconates, malonates, oxalates, phthalates, and succinates, and mixtures thereof.

An iron-containing accelerator may also include an iron-containing activator (e.g., a free radical producing compound) or an iron-containing catalyst associated with (e.g., coated or bonded to) the surface of the colloidal silica particle such as is disclosed in U.S. Pat. Nos. 7,029,508 and 7,077,880. For example, the iron-containing accelerator may be bonded with the silanol groups on the surface of the colloidal surface particles.

The amount of iron-containing accelerator in the polishing composition may be varied depending upon the oxidizing agent used and the chemical form of the accelerator. When the oxidizing agent is hydrogen peroxide (or one of its analogs) and a soluble iron-containing catalyst is used (such as ferric nitrate or hydrates of ferric nitrate), the catalyst may be present in the composition at point of use in an amount sufficient to provide a range from about 0.5 to about 3000 ppm Fe based on the total weight of the composition. For example, polishing compositions configured for bulk tungsten or molybdenum removal may include about 1 ppm Fe or more at point of use (e.g., about 5 ppm or more, about 10 ppm or more, or about 15 ppm or more). The polishing composition may include about 500 ppm Fe or less at point of use (e.g., about 200 ppm or less, about 100 ppm or less, or about 50 ppm or less). Accordingly, the point of use polishing composition may include Fe in a range bounded by any one of the above endpoints (e.g., from about 1 ppm to about 500 ppm, from about 5 ppm to about 200 ppm, from about 10 ppm to about 100 ppm, or from about 15 ppm to about 50 ppm). For tungsten or molybdenum buff applications that do not require high metal removal rates, the catalyst may be present in lower amounts, for example, from about 0.1 ppm to about 50 ppm Fe (e.g., from about 0.2 ppm to about 20 ppm or from about 0.2 to about 10 ppm) at point of use.

Embodiments of the polishing composition including an iron-containing accelerator may further include a stabilizer. Without such a stabilizer, the iron-containing accelerator and the oxidizing agent, if present, may react in a manner that degrades the oxidizing agent rapidly over time. The addition of a stabilizer tends to reduce the effectiveness of the iron-containing accelerator such that the choice of the type and amount of stabilizer added to the polishing composition may have a significant impact on CMP performance. The addition of a stabilizer may lead to the formation of a stabilizer/accelerator complex that inhibits the accelerator from reacting with the oxidizing agent, if present, while at the same time allowing the accelerator to remain sufficiently active so as to promote rapid tungsten or molybdenum polishing rates.

Useful stabilizers include phosphoric acid, organic acids such as polycarboxylic acids, phosphonate compounds, nitriles, and other ligands which bind to the metal and reduce its reactivity toward hydrogen peroxide decomposition and mixture thereof. The acid stabilizers may be used in their conjugate form, e.g., the carboxylate can be used instead of the carboxylic acid. The term “acid” as it is used herein to describe useful stabilizers also means the conjugate base of the acid stabilizer. Stabilizers can be used alone or in combination and significantly reduce the rate at which oxidizing agents such as hydrogen peroxide decompose.

Preferred stabilizers include phosphoric acid, acetic acid, phthalic acid, citric acid, adipic acid, oxalic acid, malonic acid, aspartic acid, succinic acid, glutaric acid, pimelic acid, suberic acid, azelaic acid, sebacic acid, maleic acid, glutaconic acid, muconic acid, ethylenediaminetetraacetic acid (EDTA), propylenediaminetetraacetic acid (PDTA), and mixtures thereof. The preferred stabilizers may be added to the compositions of this invention in an amount ranging from about 1 equivalent per iron-containing accelerator to about 3.0 weight percent or more (e.g., from about 1 equivalent to about 5 equivalents, or from about 3 equivalents to about 10 equivalents). As used herein, the term “equivalent per iron-containing accelerator” means one molecule of stabilizer per iron ion in the composition. For example, two equivalents per iron-containing accelerator means two molecules of stabilizer for each catalyst ion.

The polishing composition may optionally further include an oxidizing agent. The oxidizing agent may be added to the polishing composition during the slurry manufacturing process or just prior to the CMP operation (e.g., in a tank located at the semiconductor fabrication facility). Preferred oxidizing agents include inorganic or organic per-compounds. A per-compound as defined herein is a compound containing at least one peroxy group (—O—O—) or a compound containing an element in its highest oxidation state. Examples of compounds containing at least one peroxy group include but are not limited to hydrogen peroxide and its adducts such as urea hydrogen peroxide and percarbonates, organic peroxides such as benzoyl peroxide, peracetic acid, and di-t-butyl peroxide, monopersulfates (SO₅⁼), dipersulfates (S₂O₈⁼), and sodium peroxide. Examples of compounds containing an element in its highest oxidation state include but are not limited to periodic acid, periodate salts, perbromic acid, perbromate salts, perchloric acid, perchlorate salts, perboric acid, and perborate salts and permanganates. The most preferred oxidizing agent is hydrogen peroxide.

The oxidizing agent may be present in the polishing composition in substantially any suitable amount, for example, from about 0.0 wt. % to about 20 wt. % at point of use. In example embodiments configured for bulk tungsten or molybdenum removal that include a hydrogen peroxide oxidizer and a soluble iron-containing catalyst, the oxidizer may be present in the polishing composition in an amount ranging from about 0.1 wt. % to about 10 wt. % at point of use (e.g., from about 0.5 wt. % to about 5 wt. % or from about 1 wt. % to about 4 wt. %). In example embodiments configured for buff tungsten or molybdenum applications, the amount of hydrogen peroxide in the composition is generally less, for example, from about 0 wt. % to about 1 wt. %.

The polishing composition further includes an alkyl-N-oxide compound etch inhibitor. A suitable alkyl-N-oxide compound is an organic compound including an alkyl group and an N-oxide (NO) group as given in the following formula:

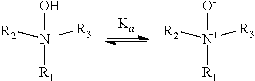

where R₁ is an alkyl group including at least 8 carbon atoms (preferably a straight chain alkyl) and R₂ and R₃ are hydrogen or alkyl. R₂ and R₃ are preferably hydrogen, methyl, or ethyl groups (containing two or less carbon atoms) and are most preferably methyl (containing a single carbon atom). In preferred embodiments, R₁ is an alkyl group including at least 10 carbon atoms (e.g., at least 12 carbon atoms). In most preferred embodiments, the alkyl-N-oxide compound includes decyldimethylamine oxide, lauryldimethylamine oxide, or a mixture thereof. A preferred lauryldimethylamine oxide compound includes a mixture of at least a first alkyl-N-oxide compound in which R₁ has 12 carbon atoms and a second alkyl-N-oxide compound in which R₁ has 14 carbon atoms. It will be appreciated that the alkyl-N-oxide may be used in an acid or conjugate base form. Such alkyl-N-oxide compounds have been found to inhibit tungsten and molybdenum etching while surprisingly also increasing polishing rates in certain polishing compositions. The disclosed polishing compositions including the alkyl-N-oxide inhibitor may therefore be particularly advantageous in advanced tungsten and molybdenum CMP operations.

The disclosed embodiments may include substantially any suitable amount of the alkyl-N-oxide compound. When the alkyl-N-oxide compound is a preferred compound in which R₁ is a straight chain alkyl having at least 10 carbon atoms and R₂ and R₃ contain two or less carbon atoms, the polishing composition may include about 2 ppm by weight or more at point of use (e.g., about 5 ppm or more, about 10 ppm or more, about 20 ppm or more, about 30 ppm or more, or about 40 ppm or more) of the alkyl-N-oxide compound. Moreover, the polishing composition may include about 500 ppm by weight or less at point of use (e.g., about 300 ppm or less, about 200 ppm or less, about 100 ppm or less, about 80 ppm or less, or about 60 ppm or less) of the alkyl-N-oxide compound. Accordingly, the polishing composition may include a concentration of the alkyl-N-oxide compound bounded by any two of the above endpoints. For example, the polishing composition may include from about 2 ppm to about 500 ppm by weight at point of use (e.g., from about 5 ppm to about 500 ppm, from about 5 ppm to about 300 ppm, from about 10 ppm to about 200 ppm, from about 20 ppm to about 100 ppm, from about 30 ppm to about 80 ppm, or from about 40 ppm to about 60 ppm) of the alkyl-N-oxide compound.

The polishing composition further include at least one supplemental (additional) etch inhibitor and/or topography control agent. Suitable inhibitor compounds may inhibit the conversion of solid tungsten or molybdenum into soluble compounds while at the same time allowing for effective removal of the metal via the CMP operation. The polishing composition may include substantially any suitable inhibitor, for example, inhibitor compounds disclosed in commonly assigned U.S. Pat. Nos. 9,238,754; 9,303,188; and 9,303,189.

Example classes of compounds that that may be useful etch inhibitors include compounds having nitrogen containing functional groups such as nitrogen containing heterocycles, alkyl ammonium ions, amino alkyls, and amino acids. Useful amino alkyl corrosion inhibitors include, for example, hexylamine, tetramethyl-p-phenylene diamine, octylamine, diethylene triamine, dibutyl benzylamine, aminopropylsilanol, aminopropylsiloxane, dodecylamine, mixtures thereof, and synthetic and naturally occurring amino acids including, for example, lysine, tyrosine, glutamine, glutamic acid, arginine, histidine, aspartic acid, cystine, and glycine (aminoacetic acid). In example embodiments including an amino alkyl inhibitor, the amino alkyl inhibitor may advantageously be present in the polishing composition (at point of use) in an amount ranging from about 1 ppm by weight to about 200 ppm by weight (e.g., from about 2 ppm to about 100 ppm or from about 4 ppm to about 40 ppm).

Suitable compounds may alternatively and/or additionally include an amine compound in solution in the liquid carrier. The amine compound (or compounds) may include a primary amine, a secondary amine, a tertiary amine, or a quaternary amine. The amine compound may further include a monoamine, a diamine, a triamine, a tetramine, or an amine based polymer having a large number of repeating amine groups (e.g., 4 or more amine groups).

Suitable compounds may alternatively and/or additionally be a cationic surfactant. The use of a cationic surfactant may advantageously reduce the metal etch rate and improve planarity (e.g., reducing dishing and/or erosion). In certain embodiments, the polishing compound may include a nitrogen containing cationic surfactant, such as a quaternary amine compound or a polyquaternary amine compound. By polyquaternary amine it is meant that the compound includes from 2 to 4 quaternary ammonium groups such that the polyquaternary amine is a diquaternary amine compound, a triquaternary amine compound, or a tetraquaternary amine compound. Diquaternary amine compounds may include, for example, N,N′-methylenebis(dimethylteradecylammonium bromide), N,N,N′,N′,N′-pentamethyl-N-tallow-1,3-propane-diammonium dichloride, N,N′-hexamethylenebis(tributylammonium hydroxide), decamethonium bromide, didodecyl-tetramethyl-1,4-butanediaminium diiodide, 1,5-dimethyl-1,5-diazoniabicyclo(3.2.2)nonane dibromide, dimethylcocoamine bis(chloroethyl) ether diquaternary ammonium salt, and the like. Triquaternary amine compounds may include, for example, N(1),N(6)-didoecyl-N(1),N(1),N(6),N(6)-tetramethyl-1,6-hexanediaminium diiodide. Tetraquaternary amine compounds may include, for example, methanetetrayltetrakis(tetramethylammonium bromide). The polyquaternary amine compound may further include a long chain alkyl group (e.g., having 10 or more carbon atoms), For example, a polyquaternary amine compound having a long chain alkyl group may include N,N′-methylenebis(dimethyltetradecylammonium bromide), N,N,N′,N′,N′-pentamethyl-N-tallow-1,3-propane-diammonium dichloride, didodecyl-tetramethyl-1,4-butanediaminium di iodide, and N(1),N(6)-didodecyl-N(1),N(1),N(6),N(6)-tetramethyl-1,6-hexanediaminium diiodide.

Suitable compounds may alternatively and/or additionally include a cationic polymer. Example cationic polymers include but are not limited to poly(vinylimidazolium), poly(methacryloyloxyethyltrimethylammonium) chloride (polyMADQUAT), poly(diallyldimethylammonium) chloride (polyDADMAC) (i.e., Polyquaternium-6), poly(dimethylamine-co-epichlorohydrin), poly[bis(2-chloroethyl) ether-alt-1,3-bis[3-(dimethylamino)propyl]urea](i.e., Polyquaternium-2), copolymers of hydroxyethyl cellulose and diallyldimethylammonium (i.e., Polyquaternium-4), copolymers of acrylamide and diallyldimethylammonium (i.e., Polyquaternium-7), quaternized hydroxyethylcellulose ethoxylate (i.e., Polyquaternium-10), copolymers of vinylpyrrolidone and quaternized dimethylaminoethyl methacrylate (i.e., Polyquaternium-11), copolymers of vinylpyrrolidone and quaternized vinylimidazole (i.e., Polyquaternium-16), Polyquaternium-24, a terpolymer of vinylcaprolactam, vinylpyrrolidone, and quaternized vinylimidazole (i.e., Polyquaternium-46), 3-Methyl-1-vinylimidazolium methyl sulfate-N-vinylpyrrolidone copolymer (i.e., Polyquaternium-44), and copolymers of vinylpyrrolidone and diallyldimethylammonium. Additionally, suitable cationic polymers include cationic polymers for personal care such as Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, and combinations thereof.

Cationic polymers may also include an amino acid monomer (such compounds may also be referred to as polyamino acid compounds). Suitable polyamino acid compounds may include substantially any suitable amino acid monomer groups, for example, including polyarginine, polyhistidine, polyalanine, polyglycine, polytyrosine, polyproline, and polylysine. In example embodiments, polylysine may be a preferred polyamino acid. It will be understood that polylysine may include ε-polylysine and/or α-polylysine composed of D-lysine and/or L-lysine. The polylysine may thus include α-poly-L-lysine, α-poly-D-lysine, ε-poly-L-lysine, ε-poly-D-lysine, and mixtures thereof. The most preferred polylysine is ε-poly-L-lysine. It will further be understood that the polyamino acid compound (or compounds) may be used in any accessible form, e.g., the conjugate acid or base and salt forms of the polyamino acid may be used instead of (or in addition to) the polyamino acid. In example embodiments including a polyamino acid compound, the polyamino acid compound may advantageously be present in the polishing composition (at point of use) in an amount ranging from about 1 ppm by weight to about 100 ppm by weight (e.g., from about 1 ppm to about 50 ppm or from about 3 ppm to about 15 ppm).

In certain advantageous embodiments, the polishing composition may include first and second distinct nitrogen containing inhibitor compounds. For example, the first inhibitor compound in the composition may include a cationic polymer such as a polyamino acid (with polylysine being preferred) and the second inhibitor compound in the composition may include an amino acid (with glycine, arginine, and a histidine being preferred).

The disclosed polishing compositions may include substantially any additional optional chemical additives. For example, the disclosed compositions may include dispersants and biocides. Such additional additives are purely optional. The disclosed embodiments are not so limited and do not require the use of any one or more of such additives. In embodiments further including a biocide, the biocide may include any suitable biocide, for example an isothiazolinone biocide known to those of ordinary skill in the art.

The polishing composition may be prepared using any suitable techniques, many of which are known to those skilled in the art. The polishing composition may be prepared in a batch or continuous process. Generally, the polishing composition may be prepared by combining the components thereof in any order. The term “component” as used herein includes the individual ingredients (e.g., the colloidal silica, the iron-containing accelerator, the amine compound, etc.).

For example, the polishing composition components (such as the iron-containing accelerator, the stabilizer, the corrosion inhibitor(s), the alkyl-N-oxide compound, and/or the biocide) may be added directly to an abrasive dispersion (such as an anionic or cationic colloidal silica dispersion). The silica dispersion and the other components may be blended together using any suitable techniques for achieving adequate mixing. Such blending/mixing techniques are well known to those of ordinary skill in the art. The oxidizing agent, when present, may be added at any time during the preparation of the polishing composition. For example, the polishing composition may be prepared prior to use, with one or more components, such as the oxidizing agent, being added just prior to the CMP operation (e.g., within about 1 minute, or within about 10 minutes, or within about 1 hour, or within about 1 day, or within about 1 week of the CMP operation). The polishing composition also may also be prepared by mixing the components at the surface of the substrate (e.g., on the polishing pad) during the CMP operation.

The polishing composition may advantageously be supplied as a one-package system comprising the abrasive particles, the iron-containing accelerator, the stabilizer, the corrosion inhibitor(s), the alkyl-N-oxide compound, and other optional components. Hydrogen peroxide may be desirably supplied separately from the other components of the polishing composition and may be combined, e.g., by the end-user, with the other components of the polishing composition shortly before use (e.g., 1 week or less prior to use, 1 day or less prior to use, 1 hour or less prior to use, 10 minutes or less prior to use, or 1 minute or less prior to use). Various other two-container, or three- or more-container, combinations of the components of the polishing composition are within the knowledge of one of ordinary skill in the art.

The polishing composition of the invention may also be provided as a concentrate which is intended to be diluted with an appropriate amount of water prior to use. In such an embodiment, the polishing composition concentrate may include the abrasive particles, the iron-containing accelerator, the stabilizer, the corrosion inhibitor(s), the alkyl-N-oxide compound, and other optional components in amounts such that, upon dilution of the concentrate with an appropriate amount of water, and an optional oxidizing agent if not already present in an appropriate amount, each component of the polishing composition will be present in the polishing composition in an amount within the appropriate ranges recited above for each component. For example, the colloidal silica and other optional components may each be present in the polishing composition in an amount that is about 2 times (e.g., about 3 times, about 4 times, about 5 times, or even about 10 times) greater than the point of use concentrations recited above for each component so that, when the concentrate is diluted with an equal volume of (e.g., 2 equal volumes of water, 3 equal volumes of water, 4 equal volumes of water, or even 9 equal volumes of water respectively), along with the oxidizing agent in a suitable amount, each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

The disclosed polishing compositions may be advantageously used to polish a substrate including a tungsten layer and/or a molybdenum layer as well as a dielectric material such as silicon oxide and/or silicon nitride. In some applications, the tungsten and molybdenum layers may contact one another, for example, a molybdenum layer may be used as a liner for tungsten plugs and/or interconnects.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate (such as the tungsten and molybdenum layers described above) to polish the substrate.

A substrate may be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

The following examples further illustrate the invention but, of course, should not be construed as in any way limiting its scope.

### Example 1

Five polishing compositions were prepared. This example demonstrates the effectiveness of the alkyl-N-oxide compound inhibitor at reducing the static etch rate of both tungsten and molybdenum. Each composition included 1335 ppm by weight malonic acid, 618 ppm by weight ferric nitrate nonahydrate (Fe(NO₃)₃·9H₂O), 24 ppm by weight epsilon poly-L-lysine, 100 ppm by weight Proxel AQ preservative, and 0.60 weight percent of a cationic colloidal silica that was treated with an amino silane compound. Each of compositions 1B-1E further included an alkyl-N-oxide compound in the amounts given in Table 1A. Composition 1B included N,N-dimethyldecylamine N-oxide and compositions 1C, 1D, and 1E included N,N-dimethyldodecylamine N-oxide. The pH of each composition was adjusted to 2.15 using nitric acid or potassium hydroxide. The final measured pH values are also given in Table 1A. The conductivity, particle size, and zeta potential of each composition were also measured and are reported in Table 1A. The particle size and zeta potential measurements were made using a Zetasizer® (Malvern Instruments).

TABLE 1A

| | Alkyl-N- | | | Particle | Zeta |
|---|---|---|---|---|---|
| Polishing | Oxide | Final | Conductivity | Size | Potential |
| Composition | (ppm) | pH | (μS/cm) | (nm) | (mV) |
| 1A | 0 | 2.14 | 3854 | 103 | 41 |
| 1B | 275 | 2.16 | 3495 | 98 | 41 |
| 1C | 137 | 2.16 | 3667 | 101 | 42 |
| 1D | 275 | 2.18 | 3497 | 102 | 42 |
| 1E | 550 | 2.12 | 4077 | 103 | 43 |

The static etch rates of tungsten and molybdenum were measured for each of the above compositions. One part of each composition was diluted with 5 parts deionized water and hydrogen peroxide. Hydrogen peroxide levels of 0.1 wt. % and 0.5 wt. % were tested. The static etch rate of tungsten was measured by immersing one inch square wafer samples (cleaved from 200 mm diameter blanket wafers having an initial W thickness of 8 kA) in the respective compositions (tungsten side up) for 5 minutes at 60 degrees C. The static etch rate of molybdenum was measured by immersing one inch square wafer samples (cleaved from 200 mm diameter blanket wafers having an initial Mo thickness of 6 kA) in the respective compositions (molybdenum side up) for 30 seconds at 25 degrees C. The SER values are reported in Table 1B. Each SER value is the average of two measurements.

TABLE 1B

| Polishing | Alkyl-N-Oxide | H₂O₂ | W SER Rate | Mo SER Rate |
|---|---|---|---|---|
| Composition | (ppm) | (wt. %) | (Å/min) | (Å/min) |
| 1A | 0 | 0.1 | 46 | 585 |
| 1A | 0 | 0.5 | 81 | 2225 |
| 1B | 46 | 0.1 | 48 | 128 |
| 1B | 46 | 0.5 | 82 | 496 |
| 1C | 23 | 0.1 | 45 | 670 |
| 1C | 23 | 0.5 | 82 | 2228 |
| 1D | 46 | 0.1 | 5 | 87 |
| 1D | 46 | 0.5 | 72 | 105 |
| 1E | 91 | 0.1 | 3 | 9 |
| 1E | 91 | 0.5 | 4 | 31 |

As is evident from the data set forth in Table 1A, the compositions including the alkyl-N-oxide inhibitor remain colloidally stable. As is evident from the data set forth in Table 1B, the alkyl-N-oxide inhibitor significantly reduces the etch rate of both molybdenum (compositions 1B, 1D, and 1E) and tungsten (compositions 1D and 1E). In particular, up to a 70× reduction in the molybdenum etch rate was observed and up to a 20× reduction in the tungsten etch rate was observed without impacting the conductivity, particle size, or zeta potential of the compositions.

### Example 2

Two polishing compositions were prepared. This example demonstrates that the alkyl-N-oxide inhibitor may increases the tungsten removal rate. Each of the polishing compositions included 0.146 weight percent of an amino-silane treated, cationic colloidal silica having an average particle size of about 120 nm, 834 ppm by weight malonic acid, 386 ppm by weight ferric nitrate nonahydrate (Fe(NO₃)₃·9H₂O), 9 ppm by weight epsilon poly-L-lysine, 20 ppm by weight L-histidine, and 16 ppm by weight Proxel AQ preservative. The pH of each composition was adjusted to 2.7 using nitric acid or potassium hydroxide and further included 2.0 weight percent hydrogen peroxide. Polishing composition 2B further included 100 ppm of N,N-dimethyldodecylamine N-oxide. Table 2A lists the final pH, conductivity, particles size and zeta potential of each composition. The particle size and zeta potential were measured using the Zetasizer® (Malvern Instruments).

TABLE 2A

| Polishing | | Conductivity | Particle | Zeta Potential |
|---|---|---|---|---|
| Composition | pH | (μS/cm) | Size (nm) | (mV) |
| 2A | 2.6 | 1461 | 124 | 41 |
| 2B | 2.7 | 1352 | 125 | 40 |

The CMP performance of polishing compositions 2A and 2B was evaluated using a Reflexion® CMP polishing tool (Applied Materials) with an VP3100 polishing pad (DuPont) and ex-situ conditioning using a Saesol C1 conditioner at 6 lbs. with DI water. Tungsten and TEOS polishing rates were obtained by polishing corresponding 300 mm blanket wafers at a downforce of 2 psi, a platen speed of 100 rpm, a head speed of 101 rpm, and a slurry flow rate of 250 mL/min. Patterned wafer polishing performance was obtained by polishing patterned wafers to optical endpoint plus 20% over polish. Removal rates are shown in Table 2B. Patterned wafer clear times (throughput) and topography data are shown in Table 2C.

TABLE 2B

| Polishing | W RR | TEOS RR | W Pattern | W:TEOS |
|---|---|---|---|---|
| Composition | (Å/min) | (Å/min) | RR (Å/min) | Selectivity |
| 2A | 1309 | 31 | 1429 | 42 |
| 2B | 1788 | 35 | 2007 | 51 |

TABLE 2C

| Polishing | W Clear | Barrier Clear | Erosion | Dishing |
|---|---|---|---|---|
| Composition | Time (sec) | Time (sec) | (Å) | (Å) |
| 2A | 80 | 15 | 166 | −24 |
| 2B | 57 | 12 | 179 | 33 |

As is evident from the data set forth in tables 2B and 2C, polishing composition 2B (including the alkyl-N-oxide inhibitor) has a significantly improved tungsten removal rate (over 35% improved) as compared to composition 2A. The removal rate enhancement was also evident in the wafer clear times as composition 2B achieved a 30 percent reduction in tungsten clear time and a 20 percent reduction in barrier clear time. Moreover, composition 2B achieved similar erosion and dishing to the control (2A) indicating the inventive compositions may achieve comparable erosion and dishing while providing significantly enhanced throughput.

### Example 3

Ten polishing compositions were prepared. This example demonstrates that the alkyl-N-oxide inhibitor increases the tungsten removal rate across a range of concentrations. Each of the polishing compositions included an amino-silane treated, cationic colloidal silica having an average particle size of about 120 nm, malonic acid, ferric nitrate nonahydrate (Fe(NO₃)₃·9H₂O), epsilon poly-L-lysine, L-histidine, and Proxel AQ preservative. The pH of each composition was adjusted to 2.7 using nitric acid or potassium hydroxide and further included 2.0 weight percent hydrogen peroxide. Polishing composition 3B-3J further included N,N-dimethyldodecylamine N-oxide. Each composition included 20 ppm by weight of the L-histidine and 16 ppm by weight of the preservative. Table 3A lists the amounts of the colloidal silica (CS), malonic acid (MA), ferric nitrate nonahydrate (FE), polylysine (EPLL), and N,N-dimethyldodecylamine N-oxide (DDAO) in each composition at point of use in units of parts per million by weight (the compositions were initially prepared as 6× concentrates). Table 3B lists the final pH, conductivity, particle size and zeta potential of each composition. The particle size and zeta potential were measured using the Zetasizer® (Malvern Instruments).

TABLE 3A

| Polishing | | | | | |
|---|---|---|---|---|---|
| Composition | CS | MA | FE | EPLL | DDAO |
| 3A | 1460 | 834 | 386 | 9 | 0 |
| 3B | 1460 | 334 | 155 | 9 | 50 |
| 3C | 1460 | 334 | 155 | 9 | 100 |
| 3D | 1460 | 335 | 155 | 9 | 150 |
| 3E | 1460 | 501 | 232 | 9 | 50 |
| 3F | 1000 | 501 | 232 | 9 | 50 |
| 3G | 1460 | 335 | 155 | 11 | 50 |
| 3H | 1460 | 501 | 232 | 11 | 50 |
| 3I | 1460 | 501 | 232 | 13 | 50 |
| 3J | 1000 | 501 | 232 | 11 | 50 |

TABLE 3B

| Polishing | | Conductivity | Particle | Zeta Potential |
|---|---|---|---|---|
| Composition | pH | (μS/cm) | Size (nm) | (mV) |
| 3A | 2.6 | 1455 | 122 | 39 |
| 3B | 2.7 | 903 | 126 | 38 |
| 3C | 2.8 | 865 | 118 | 42 |
| 3D | 2.8 | 821 | 125 | 40 |
| 3E | 2.7 | 1057 | 126 | 44 |
| 3F | 2.7 | 1093 | 127 | 40 |
| 3G | 2.7 | 857 | 123 | 41 |
| 3H | 2.7 | 1057 | 125 | 41 |
| 3I | 2.7 | 1101 | 124 | 42 |
| 3J | 2.7 | 1095 | 127 | 40 |

The CMP performance of each polishing composition was evaluated using a Reflexion® CMP polishing tool (Applied Materials) with an VP3100 polishing pad (Dupont) and ex-situ conditioning using a Saesol C1 conditioner at 6 lbs. with DI water. Tungsten and TEOS polishing rates were obtained by polishing corresponding 300 mm blanket wafers at a downforce of 2 psi, a platen speed of 100 rpm, a head speed of 101 rpm, and a slurry flow rate of 250 mL/min. Patterned wafer polishing performance was obtained by polishing patterned wafers to optical endpoint plus 20% over polish. Removal rates are shown in Table 3C. Patterned wafer clear times (throughput) and topography data are shown in Table 3D.

TABLE 3C

| Polishing | W RR | TEOS RR | W Pattern | W:TEOS |
|---|---|---|---|---|
| Composition | (Å/min) | (Å/min) | RR (Å/min) | Selectivity |
| 3A | 1296 | 29 | 1464 | 45 |
| 3B | 1796 | 19 | 2196 | 95 |
| 3C | 1547 | 18 | 1960 | 86 |
| 3D | 1050 | 19 | 1677 | 55 |
| 3E | 1801 | 21 | 2184 | 86 |
| 3F | 1732 | 18 | 2088 | 96 |
| 3G | 1782 | 18 | 2152 | 99 |
| 3H | 1799 | 19 | 2154 | 95 |
| 3I | 1727 | 18 | 2075 | 96 |
| 3J | 1591 | 18 | 2017 | 88 |

TABLE 3D

| Polishing | W Clear | Barrier Clear | Erosion | Dishing |
|---|---|---|---|---|
| Composition | Time (sec) | Time (sec) | (Å) | (Å) |
| 3A | 94 | 13 | 118 | −30 |
| 3B | 69 | 15 | 184 | 63 |
| 3C | 73 | 12 | 152 | 72 |
| 3D | 86 | 15 | 217 | 64 |
| 3E | 71 | 17 | 212 | 59 |
| 3F | 72 | 16 | 140 | 45 |
| 3G | 71 | 16 | 145 | 33 |
| 3H | 72 | 17 | 155 | 32 |
| 3I | 70 | 13 | 148 | −25 |
| 3J | 77 | 17 | 85 | 23 |

As is evident from the data set forth in tables 3C and 3D, polishing compositions 3B-3J (including the alkyl-N-oxide inhibitor) had significantly improved tungsten removal rates as compared to composition 3A (despite lower catalyst concentrations and sometimes higher polylysine concentrations). The removal rate enhancement was also evident in the wafer clear times as compositions 3B-3J achieved superior clear times as compared to composition 3A. The erosion and dishing results set forth in Table 3D further demonstrate that the inventive composition may be tuned to achieve a range of performance metrics while maintaining high throughput.

### Example 4

Two polishing compositions were prepared. Each of the polishing compositions included 0.1 weight percent of an amino-silane treated, cationic colloidal silica having an average particle size of about 120 nm, 501 ppm by weight malonic acid, 232 ppm by weight ferric nitrate nonahydrate (Fe(NO₃)₃·9H₂O), 3.75 ppm benzotriazole, and 16.7 ppm by weight Proxel AQ preservative. The pH of each composition was adjusted to 2.7 using nitric acid or potassium hydroxide and further included 2.0 weight percent hydrogen peroxide. Polishing compositions 4B further included 100 ppm by weight of N,N-dimethyldodecylamine N-oxide.

The CMP performance of polishing compositions 4A and 4B was evaluated using a Reflexion® CMP polishing tool (Applied Materials) with an VP3100 polishing pad (DuPont) and ex-situ conditioning using a Saesol C1 conditioner at 6 lbs. with DI water. Tungsten polishing rates were obtained by polishing 300 mm blanket wafers at a downforce of 2 psi, a platen speed of 100 rpm, a head speed of 101 rpm, and a slurry flow rate of 250 mL/min. Patterned wafer polishing performance was obtained by polishing patterned wafers to optical endpoint plus 20% over polish. Removal rates are shown in Table 4A. Patterned wafer topography is shown on 1×1 and 3×1 micron line arrays in Table 4B.

TABLE 4A

| Polishing | W RR | W Pattern |
|---|---|---|
| Composition | (Å/min) | RR (Å/min) |
| 4A | 446 | 1002 |
| 4B | 935 | 1737 |

TABLE 4B

| Polishing | Erosion | Dishing | Erosion | Dishing |
|---|---|---|---|---|
| Composition | 1 × 1 (Å) | 1 × 1 (Å) | 3 × 1 (Å) | 3 × 1 (Å) |
| 4A | 393 | 299 | 604 | 259 |
| 4B | 128 | 43 | 260 | 74 |

As is evident from the data set forth in tables 4A and 4B, polishing composition 4B (including the alkyl-N-oxide inhibitor) had significantly improved tungsten removal rate as compared to composition 4A. Moreover, composition 4B exhibited superior erosion and dishing across a range of features. It is evident that the alkyl-N-oxide inhibitor may optionally replace (rather than supplement) other inhibitors and/or topography control agents.

### Example 5

Five polishing compositions were prepared. Each of the polishing compositions included 0.125 weight percent of an amino-silane treated, cationic colloidal silica having an average particle size of about 120 nm, 501 ppm by weight malonic acid, 232 ppm by weight ferric nitrate nonahydrate (Fe(NO₃)₃·9H₂O), 3.75 ppm benzotriazole, and 16.7 ppm by weight Proxel AQ preservative. The pH of each composition was adjusted to 2.7 using nitric acid or potassium hydroxide and further included 2.0 weight percent hydrogen peroxide. Polishing compositions 5B-5E further included 21.8 μM of an N-oxide compound, with composition 5B including 50 ppm by weight N,N-dimethyldodecylamine N-oxide (DDAO), composition 5C including 43.9 ppm by weight tributylamine N-oxide (TBAO), composition 5D including 24.2 ppm by weight trimethylamine N-oxide (TMAO), and composition 5E including 20.8 ppm by weight pyridine N-oxide (PNO).

The CMP performance of polishing compositions 5A-5E was evaluated using a Mirra® CMP polishing tool (Applied Materials) with an E6088 polishing pad (Entegris) and ex-situ conditioning using a Saesol C1 conditioner at 6 lbs. with DI water. Patterned wafer performance was evaluated by polishing 200 mm tungsten patterned wafers at a downforce of 2.5 psi, a platen speed of 100 rpm, a head speed of 101 rpm, and a slurry flow rate of 100 mL/min to optical endpoint plus 20% over polish. Patterned wafer performance is shown in Table 5.

TABLE 5

| | | W | W | Barrier | | |
|---|---|---|---|---|---|---|
| | | Pattern | Clear | Clear | Erosion | Dishing |
| Polishing | N-oxide | RR | Time | Time | 1 × 1 | 1 × 1 |
| Composition | compound | (Å/min) | (sec) | (sec) | (Å) | (Å) |
| 5A | | 2816 | 51 | 11 | 236 | 249 |
| 5B | DDAO | 2379 | 61 | 16 | 232 | 105 |
| 5C | TBAO | 2532 | 59 | 9 | 250 | 301 |
| 5D | TMAO | 2677 | 54 | 12 | 323 | 278 |
| 5E | PNO | 2713 | 53 | 12 | 314 | 281 |

As is evident in Table 5, composition 5B (including the alkyl-N-oxide inhibitor) exhibited superior dishing as compared to compositions 5A and 5C-5E.

### Example 6

Two polishing compositions were prepared. Each of the polishing compositions included 4 weight percent of a colloidal silica having an average particle size of about 80 nm, 180 ppm by weight malonic acid, 180 ppm by weight ferric nitrate nonahydrate (Fe(NO₃)₃·9H₂O), 0.18 weight percent tetrabutylammonium hydroxide, 0.1 weight percent L-glutamic acid, 35 ppm by weight epsilon poly-L-lysine, and 50 ppm Proxel AQ preservative. The pH was adjusted to 3.2 using potassium hydroxide or nitric acid. Each composition further included 3 weight percent hydrogen peroxide. Composition 6B further included 50 ppm by weight N,N-dimethyldodecylamine N-oxide.

The CMP performance of polishing compositions 6A and 6B was evaluated using a Mirra® CMP polishing tool (Applied Materials) with an E6088 polishing pad (Entegris) and ex-situ conditioning using a Saesol C1 conditioner at 6 lbs. with DI water. Blanket and patterned wafer performance was evaluated by polishing 200 mm wafers at a downforce of 2.5 psi, a platen speed of 100 rpm, a head speed of 101 rpm, and a slurry flow rate of 100 mL/min to optical endpoint plus 20% over polish. Removal rates are shown in Table 6A. Patterned wafer topography data for lxi and 3×1 micron line arrays are shown in Table 6B.

TABLE 6A

| Polishing | W RR | TEOS RR | W Pattern |
|---|---|---|---|
| Composition | (Å/min) | (Å/min) | RR (Å/min) |
| 6A | 2532 | 997 | 2997 |
| 6B | 2485 | 979 | 2667 |

TABLE 6B

| Polishing | Erosion | Dishing | Erosion | Dishing |
|---|---|---|---|---|
| Composition | 1 × 1 (Å) | 1 × 1 (Å) | 3 × 1 (Å) | 3 × 1 (Å) |
| 6A | 289 | 64 | 679 | 114 |
| 6B | 210 | 58 | 538 | 113 |

As is evident from the data set forth in Tables 6A and 6B, composition 6B (including the alkyl-N-oxide inhibitor) exhibited superior erosion as compared to composition 6A.

It will be understood that the recitation of ranges of values herein are merely intended to serve as a shorthand method of referring individually to each separate value falling within the range, unless otherwise indicated herein, and each separate value is incorporated into the specification as if it were individually recited herein. All methods described herein may be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition comprising:
a liquid carrier;
colloidal silica particles dispersed in the liquid carrier;
an iron-containing polishing accelerator;
a stabilizer bound to the iron-containing polishing accelerator;
an alkyl-N-oxide compound including a first alkyl group having at least 8 carbon atoms; and
a pH of less than about 4.

2. The composition of claim 1, wherein the alkyl-N-oxide compound includes second and third alkyl groups having 2 or less carbon atoms.

3. The composition of claim 2, wherein the second and third alkyl groups are methyl groups.

4. The composition of claim 1, wherein the alkyl-N-oxide compound comprises at least a first alkyl-N-oxide compound in which the first alkyl group has 12 carbon atoms and a second alkyl-N-oxide compound in which the first alkyl group has 14 carbon atoms.

5. The composition of claim 1, wherein the alkyl-N-oxide compound comprises decyldimethylamine oxide, lauryldimethylamine oxide, or a mixture thereof.

6. The composition of claim 1, comprising from about 10 ppm to about 200 ppm by weight of the alkyl-N-oxide compound at point of use.

7. The composition of claim 1, further comprising a hydrogen peroxide oxidizer.

8. The composition of claim 1, having a pH in a range from about 1 to about 3.5.

9. The composition of claim 1, wherein the iron-containing polishing accelerator comprises a soluble iron catalyst and the stabilizer comprises a polycarboxylic acid stabilizer bound to the soluble iron catalyst.

10. The composition of claim 1, further comprising at least one inhibitor of tungsten etching, the inhibitor of tungsten etching including at least one nitrogen containing group.

11. The composition of claim 10, wherein the at least one inhibitor of tungsten etching comprises a polyamino acid compound.

12. The composition of claim 10, wherein the at least one inhibitor of tungsten etching comprises an amino acid compound.

13. The composition of claim 10, wherein the inhibitor of tungsten etching comprises first and second distinct inhibitors of tungsten etching.

14. The composition of claim 13, wherein the first inhibitor of tungsten etching comprises a polyamino acid compound and the second inhibitor of tungsten etching comprises an amino acid compound.

15. The composition of claim 1, wherein the colloidal silica particles comprise cationic colloidal silica particles that have an aminosilane compound bonded to an external surface thereof.

16. The composition of claim 1, further comprising a cationic surfactant selected from tetrabutylammonium, tetrapentylammonium, tetrabutylphosphonium, tributylmethylphosphonium, tributyloctylphosphonium, benzyltributylammonium, and mixtures thereof such that the colloidal silica particles have a positive zeta potential in the composition of greater than about 10 mV.

17. The polishing composition of claim 1, wherein:
the iron-containing accelerator comprises a soluble iron catalyst and the stabilizer comprises a polycarboxylic acid stabilizer bound to the soluble iron catalyst;
the alkyl-N-oxide compound comprises decyldimethylamine oxide, lauryldimethylamine oxide, or a mixture thereof; and
the composition further comprises at least one of a polyamino acid compound and an amino acid compound.

18. A method of chemical mechanical polishing a substrate, the method comprising:
(a) contacting the substrate with the polishing composition of claim 1;
(b) moving the polishing composition relative to the substrate; and
(c) abrading the substrate to remove a portion of at least one molybdenum layer or at least one tungsten layer from the substrate and thereby polish the substrate.

19. The method of claim 18, wherein abrading the substrate in (c) removes a portion of at least one molybdenum layer and a portion of at least one tungsten layer from the substrate to thereby polish the substrate.

20. The method of claim 19, wherein the at least one molybdenum layer and at the least one tungsten layer contact one another in the substrate.
